(19) United States
(12) Patent Application Publication
(10) Pub. No.: US 2009/0057739 A1
(43) Pub. Date: Mar. 5, 2009

(54) Ge channel device and method for fabricating ge channel device

(75) Inventors: Hiroshi Iwai, Yokohama-shi (JP); Takeo Hattori, Yokohama-shi (JP); Kazuo Tsutsui, Yokohama-shi (JP); Kuniyuki Kakushima, Yokohama-shi (JP); Parhat Ahmet, Yokohama-shi (JP); Jaeyeol Song, Yokohama-shi (JP); Masaki Yoshimaru, Tokyo (JP); Yasuyoshi Mishima, Ebina-shi (JP); Tomonori Aoyama, Yokohama-shi (JP); Hiroshi Oji, Hamamatsu-shi (JP); Yoshitake Kato, Tokyo (JP)

Correspondence Address: STAAS & HALSEY LLP, SUITE 700, 1201 NEW YORK AVENUE, N.W., WASHINGTON, DC, 20005, US

(73) Assignee: Tokyo Institute of Technology, Yokohama (JP)

(21) Appl. No.: 12/230,448

(22) Filed: Aug. 28, 2008

(30) Foreign Application Priority Data
Aug. 28, 2007 (JP) 2007-221605

(51) Int. Cl. H01L 29/78; H01L 21/3205

(52) U.S. Cl. 257/296; 438/585; 257/E29.255

(57) ABSTRACT

The Ge channel device comprises: a Ge channel layer (2); a Si-containing interface layer (4) formed on the Ge channel layer (2); a La₂O₃ layer (6) formed on the interface layer (4); and an electrically conductive layer (8) formed on the La₂O₃ layer (6). In this device, the Si-containing interface layer (4) functions to suppress the diffusion of Ge atoms into the La₂O₃ layer (6) and thereby prevents the formation of Ge oxide in the La₂O₃ layer (6); accordingly, a Ge channel device whose C-V characteristic exhibits only a small hysteresis can be achieved.

### CROSS-REFERENCE TO RELATED APPLICATION

This application claims priority of Japanese Patent Application No. 2007-221605, filed on Aug. 28, 2007.

### BACKGROUND OF THE INVENTION

1. Field of the Invention

The present invention relates to a semiconductor device using Ge as a channel material and a method for fabricating such a device, and more particularly to a Ge channel device using La₂O₃ as a gate insulating film material and a method for fabricating such a device.

2. Prior Art

The need for higher-speed and lower-power consumption LSIs (large-scale integrated circuits) has been growing more than ever before. To increase the operating speed of LSIs that use Si as a channel material, a lot of effort has been expended to miniaturize MOS devices that form the basic elements of LSIs. As a result of such effort, the gate length of MOS devices has now been reduced to several tens of nanometers, almost reaching the limit of miniaturization. In view of this, to develop LSIs capable of higher speed operation, research is currently directed toward using a Ge semiconductor to replace a Si semiconductor as the channel material. The reason is that, compared with Si, Ge has excellent electronic properties, in particular, high carrier mobility. The higher the carrier mobility, the faster the LSI can function.

However, Ge has a drawback that its oxides are chemically and thermodynamically unstable, and as a result, it is difficult to stably protect the surface of a Ge substrate. For this reason, not much progress has been made in the development of LSIs using Ge substrates. However in recent years, various kinds of dielectrics that can stably protect the Ge substrate surface have been found, and LSIs using Ge substrates have been drawing attention because of their future potential (for example, refer to Japanese Unexamined Patent Publication No. 2005-191293).

Noting that La₂O₃ has high permittivity and its bandgap is larger than other dielectric materials, the present inventors have been working on fabricating Ge channel devices using La₂O₃ as a gate insulating film material.

FIG. 1 shows the structure of a Ge-MOS capacitor 100 as one example of such a device. In the figure, reference numeral 102 is a Ge semiconductor substrate for forming a Ge channel, 104 is a La₂O₃ layer formed, for example, by electron-beam evaporation on the Ge semiconductor substrate 102, and 106 is an electrode layer formed by depositing a metal such as Pt or W on the La₂O₃ layer 104, for example, by electron-beam evaporation. Here, the La₂O₃ layer forms a gate insulating film.

After the fabrication, the C-V characteristic of the Ge-MOS capacitor 100 having the structure shown in FIG. 1 was measured in order to evaluate its electrical characteristic. However, it was found that the C-V characteristic exhibited appreciable hysteresis (refer to FIG. 4 to be described later), which would present a serious problem when forming a switching device such as a transistor. To identify the cause, the photoelectron spectrum of the capacitor 100 was measured, and the result showed a peak peculiar to Ge oxide (especially, suboxide); it was thus found that Ge oxide was grown in the capacitor 100 of the structure shown in FIG. 1.

In practice, before depositing La₂O₃ on a Ge substrate, the Ge substrate is cleaned and any Ge oxide formed on the surface of the Ge substrate is removed, for example, by heating; therefore, no peaks associated with Ge oxide should normally appear in the photoelectron spectrum. Accordingly, the peak appearing in the photoelectron spectrum was presumably due to the Ge oxide grown during the fabrication of the capacitor 100. That is, it is presumed that, during the heating step in the fabrication process of the capacitor 100, Ge atoms in the Ge substrate were diffused into the La₂O₃ layer where the Ge atoms combined with oxygen contained in the La₂O₃ layer, resulting in the formation of the Ge oxide.

Accordingly, to achieve a Ge channel device whose C-V characteristic exhibits only a small hysteresis, it is essential to develop a novel structure and a novel fabrication method for suppressing the diffusion of Ge into the La₂O₃ layer during the heating step and thereby preventing the formation of Ge oxide in the La₂O₃ layer.

### SUMMARY OF THE INVENTION

In view of the foregoing, it is an object of the present invention to achieve a Ge channel device having a novel structure that can effectively prevent the Ge atoms contained in the substrate from diffusing into the La₂O₃ layer during the heating step in the fabrication process of the Ge channel device, and to provide a method for fabricating a device having such a structure.

A Ge channel device that achieves the above object comprises: a Ge channel layer; a Si-containing interface layer formed on the Ge channel layer; a La₂O₃ layer formed on the interface layer; and an electrically conductive layer formed on the La₂O₃ layer.

In the above Ge channel device, the Si-containing interface layer may be formed to have a layer thickness of 0.5 to 2 nm.

In the above Ge channel device, the Si-containing interface layer may contain either Si or silicate or La-silicate or may contain all of them.

In the above Ge channel device, in order to operate the device as a MOS capacitor, a second electrically conductive layer may be formed on a surface of the Ge channel layer opposite to the surface thereof on which the interface layer is formed.

In the above Ge channel device, the Ge channel layer may contain source and drain regions.

A method for fabricating a Ge channel device, which achieves the above object, comprises the steps of: forming a Si-containing interface layer on a channel layer of Ge; forming a gate insulating film of La₂O₃ on the interface layer; and forming an electrically conductive material layer on the gate insulating film.

In the above method, the step of forming the interface layer may be accomplished by depositing Si on the channel layer by electron-beam evaporation.

In the above method, the interface layer may be formed to have a layer thickness of 0.5 to 2 nm.

The above method may further includes the step of heat-treating the channel layer after forming the electrically conductive material layer.

In the above method, the step of forming the Si-containing interface layer on the channel layer of Ge may be carried out after removing a Ge oxide film grown on a surface of the channel layer on which the interface layer is to be formed.

### EFFECT OF THE INVENTION

According to the Ge channel device and its fabrication method of the invention, the interface layer containing Si is interposed between the Ge channel layer and the La₂O₃ layer. Therefore, the Si interface layer functions to prevent Ge contained in the Ge channel layer from being thermally diffused during the heat treating step, and Ge atoms are thus prevented from moving into the La₂O₃ layer. In this way, the formation of Ge oxide in the La₂O₃ layer is suppressed, achieving a Ge channel device having an excellent electrical characteristic by greatly reducing the hysteresis in the C-V characteristic.

### BRIEF DESCRIPTION OF THE DRAWINGS

FIG. 1 is a diagram showing the structure of a prior art Ge channel device having a dielectric layer formed from La₂O₃.

FIG. 2(a) is a diagram showing a step in a Ge channel device fabrication process according to one embodiment of the present invention.

FIG. 2(b) is a diagram showing a step that follows the step shown in FIG. 2(a).

FIG. 2(c) is a diagram showing a step that follows the step shown in FIG. 2(b).

FIG. 2(d) is a diagram showing a step that follows the step shown in FIG. 2(c).

FIG. 3 is a diagram showing the photoelectron spectrum of the Ge channel device fabricated by the process shown in FIGS. 2(a) to 2(d).

FIG. 4 is a diagram showing the C-V characteristic of the Ge channel device fabricated by the process shown in FIG. 2.

FIG. 5 is a diagram showing the structure of a Ge capacitor device that can be fabricated using the process shown in FIGS. 2(a) to 2(d).

FIG. 6 is a diagram showing the structure of a Ge-MOS transistor that can be fabricated using the process shown in FIG. 2.

### DESCRIPTION OF THE PREFERRED EMBODIMENTS

The present inventors have discovered that diffusion of Ge and the growth of a suboxide can be suppressed by interposing an Si layer between La₂O₃ and a Ge semiconductor substrate. In the case of a semiconductor substrate formed from Si, the growth of suboxide is reduced compared with the case of the Ge substrate; rather, it tends to form La-silicate, and the hysteresis in the C-V characteristic of the resulting semiconductor substrate is also reduced. In view of this, the present inventors considered suppressing the diffusion of Ge and the growth of suboxide by interposing an Si layer between the Ge semiconductor substrate and the La₂O₃ layer that forms the gate insulating film, and fabricated the Ge channel device of the present invention as will be described hereinafter.

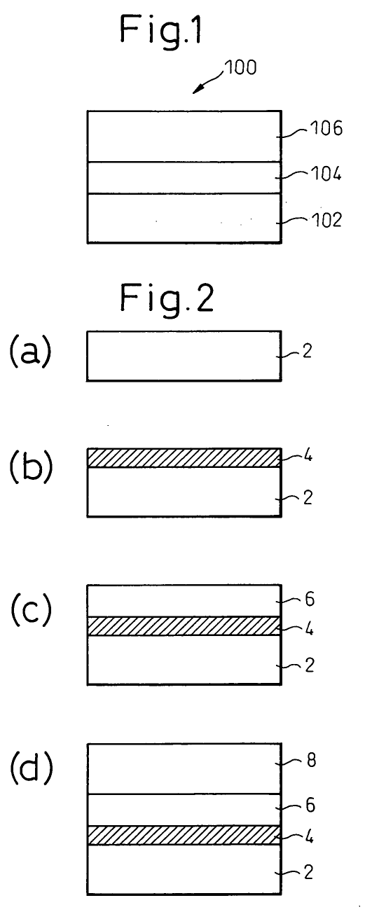

FIGS. 2(a) to 2(d) are diagrams showing the process steps for fabricating the Ge channel device according to the present invention. In FIG. 1 and subsequent figures, the thicknesses of the respective layers are exaggerated, and the thickness ratio shown in each figure does not represent the actual thickness ratio. First, as shown in FIG. 2(a), the Ge semiconductor substrate 2 for forming the Ge channel therein is prepared. After cleaning, the Ge semiconductor substrate 2 is placed in an ultra-high vacuum deposition chamber (not shown) where the native Ge oxide film formed on the semiconductor substrate surface is removed by heating.

Next, Si is deposited by electron-beam evaporation in the ultra-high vacuum deposition chamber to form a Si interface layer 4 as shown in FIG. 2(b). The thickness of the Si interface layer 4 is about 0.5 to 2 nm. Further, by performing electron-beam evaporation in the same ultra-high vacuum deposition chamber, a La₂O₃ layer 6 that functions as the gate insulating film is formed over the Si interface layer 4, as shown in FIG. 2(c). During this step, the Ge semiconductor substrate 2 is held at 250° C. In one example, the La₂O₃ layer 6 was formed to a thickness of 5.0 nm to 6.0 nm.

After that, an upper electrode layer 8 is formed on top of the layer 6 by electron-beam evaporation, as shown in FIG. 2(d). For the material of the electrode layer 8, use can be made, for example, of Pt or W. The thickness of the upper electrode layer 8 is several nanometers when measuring the photoelectron spectrum and several tens of nanometers when measuring the electrical characteristic. In the case of the device having the structure of FIG. 2(d), a back electrode (not shown) for measuring the electrical characteristic is formed after performing heat treatment in a nitrogen atmosphere. The heat treatment is performed, for example, for five minutes in a nitrogen atmosphere held at 500° C.

It is presumed that, as a result of the heat treatment, some of the Si atoms in the Si interface layer 4 combine with the oxygen contained in the La₂O₃ layer 6 to form various kinds of silicates such as SiO, SiO₂, etc. or combine with La to form La-silicate. Therefore, the completed Ge channel device contains these silicates in the Si interface layer 4.

To investigate the effect of the Si interface layer 4 in suppressing the growth of Ge suboxide, the spectrum was measured by photoelectron spectroscopy, along with the measurement of the C-V characteristic.

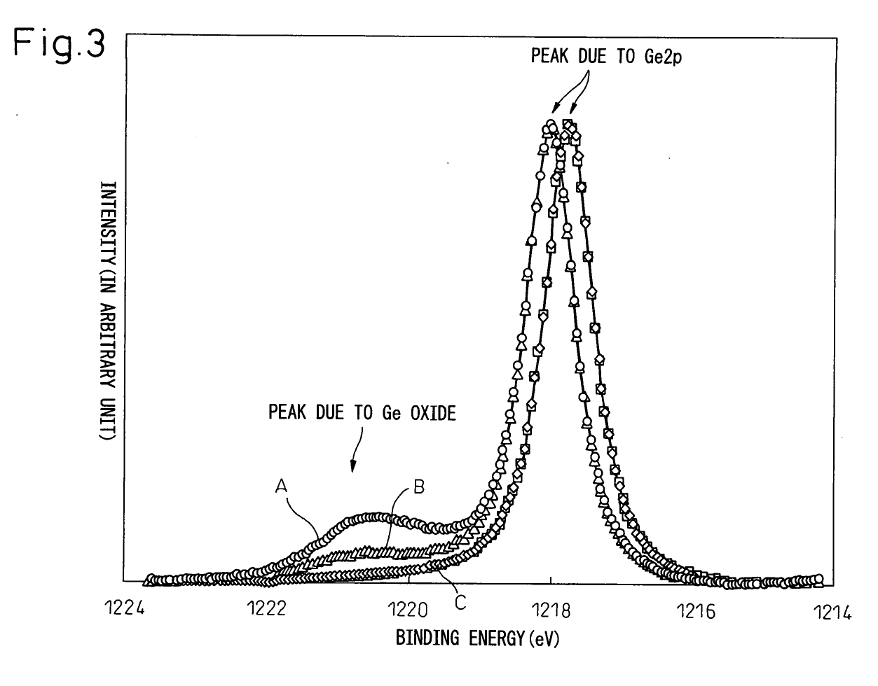

FIG. 3 is a diagram showing the photoelectron spectrum of the Pt/La₂O₃/Si/Ge structure; more specifically, the diagram shows how the photoelectron spectrum changes when the thickness of the Si interface layer 4 is varied. In particular, FIG. 3 shows the spectrum in the vicinity of the peak due to the 2p electron of Ge. The measurement was performed after heat-treating the Pt/La₂O₃/Si/Ge structure for five minutes in a 500° C. nitrogen atmosphere. In the figure, the ordinate represents the emission intensity in an arbitrary unit, and the abscissa represents the binding energy in eV.

Curve A shows the spectrum when the thickness of the Si interface layer was 0, i.e., when the Si interface layer was not provided, and curve B shows the spectrum when the thickness of the Si interface layer was not greater than 0.5 nm, while curve C shows the spectrum when the thickness of the Si interface layer was 1.0 to 1.5 nm. In the energy range shown, two distinct peaks were observed in the spectrum waveform. The peak near 1218 eV was presumably due to the Ge 2p electron, while the peak in the region of 1219 eV to 1222 eV was presumably due to Ge oxide.

It is presumed that the peak due to Ge oxide contains emission peaks due to Ge suboxides GeOx where x is 0.5, 1, 1.5, etc. The spectrum curve A for the case where no Si interface layer was provided exhibits a relatively large peak in the region of 1219 eV to 1222 eV. Therefore, this structure is considered to contain an appreciable amount of Ge oxide.

The spectrum curve B for the case where the Si interface layer was formed to a thickness not greater than 0.5 nm exhibits a slight peak in the region of 1219 eV to 1222 eV. Therefore, this structure is considered to contain Ge oxide, though in a trace amount. On the other hand, the spectrum curve C in the case where the Si interface layer was formed to a thickness of 1.0 to 1.5 nm hardly exhibits any observable peak in the region of 1219 eV to 1222 eV. Therefore, this structure is considered to contain very little of the Ge oxide. Since the Ge diffused into the La₂O₃ layer remains therein in the form of oxide, the results of FIG. 3 show that when the thickness of the Si interface layer is 1.0 to 1.5 nm or greater, the diffusion of Ge into the La₂O₃ layer due to the heat treatment and the growth of Ge suboxide can be suppressed.

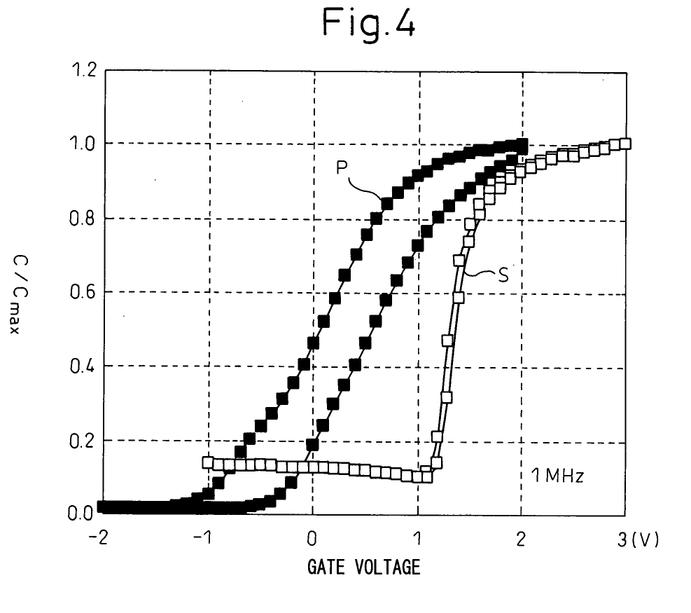

FIG. 4 is a diagram showing the C-V characteristic curve S of a W/La₂O₃/Si(thickness not greater than 2 nm)/Ge structure for comparison with the C-V characteristic curve P of a W/La₂O₃/Ge structure. The C-V characteristics of these structures were measured after heat-treating them for five minutes in a 500° C. nitrogen atmosphere. As can be seen from the figure, the C-V characteristic curve P of the W/La₂O₃/Ge structure having no Si interface layer exhibits a marked hysteresis, and, the C/Cmax value also gently rises in the gate voltage region of −1 V to 1 V. Accordingly, with the W/La₂O₃/Ge structure having no Si interface layer, it is difficult to achieve a semiconductor device having an excellent switching characteristic.

On the other hand, the C-V characteristic curve S of the W/La₂O₃/Si/Ge structure having a Si interface layer of thickness not greater than 2 nm exhibits only a slight hysteresis. Further, in the case of the curve S, the C/Cmax value steeply rises near the gate voltage 1 V; it can therefore be seen that a semiconductor device having an excellent switching characteristic can be formed using this structure.

As described above, in the Ge channel device according to the present invention, since the Si interface layer (with thickness of about 0.5 to 2 nm) is interposed between the Ge substrate layer and the La₂O₃ dielectric layer, the diffusion of Ge into La₂O₃ can be suppressed while also suppressing the growth of suboxide; as a result, a Ge channel device having an excellent electrical characteristic can be formed.

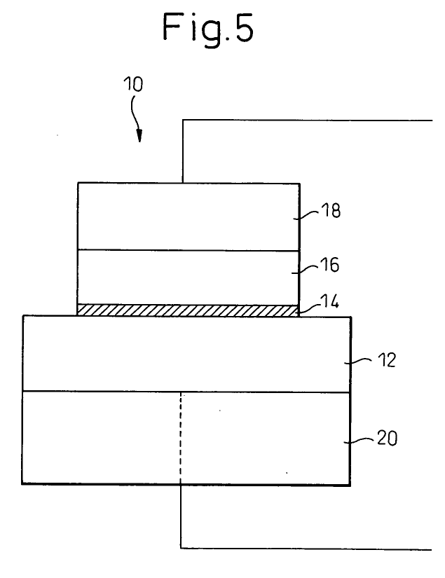

FIG. 5 is a diagram showing a capacitor device 10 that can be fabricated using the W(Pt)/La₂O₃/Si/Ge structure according to the present invention. In the figure, reference numeral 12 indicates the Ge semiconductor substrate, 14 the Si interface layer, 16 the La₂O₃ layer, and 18 the electrode layer. The structure of each of these layers is the same as that described with reference to FIG. 2. In this device 10, the Ge semiconductor substrate 12 can be formed on a semiconductor substrate 20, for example, by epitaxial growth. This facilitates the handling of the device. Alternatively, a SiO₂ layer may be formed on the Si semiconductor substrate 20, and the Ge semiconductor substrate 12 may be grown on top of that.

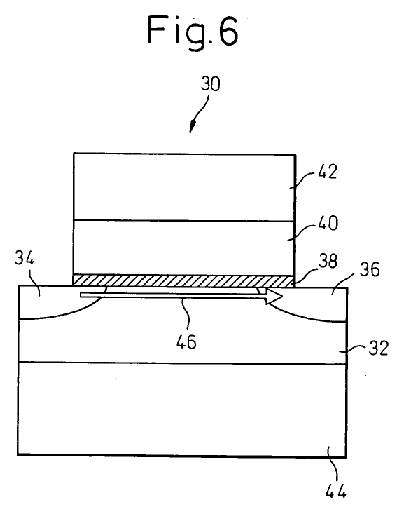

FIG. 6 is a diagram showing the structure of a Ge-MOS transistor 30 that can be fabricated using the Ge channel device according to the present invention. The Ge channel layer 32 is formed on a supporting substrate 44. The Ge channel layer 32 contains source and drain regions 34 and 36 formed by diffusing impurities. Reference numeral 38 indicates the Si interface layer, 40 the La₂O₃ layer, and 42 the electrode layer formed from W or Pt or the like. The Si interface layer 38, the La₂O₃ layer 40, and the electrode layer 42 can be formed on the Ge channel layer 32 by using the method of the embodiment shown in FIG. 2.

Though not shown in FIG. 6, the source and drain electrodes are respectively formed on the source and drain regions 34 and 36, thus forming a MOS transistor having a Ge channel 46. The electrode layer 42 forms the gate electrode, and the La₂O₃ layer 40 forms the gate insulating film, and by controlling the voltage applied to the gate electrode 42, the conduction state of the channel 46 between the source and drain regions can be controlled, and the device can thus be operated as a switching device. From the C-V characteristic measured of the capacitor structure, it is expected that this transistor device has an excellent electrical characteristic sufficient for practical use.

What is claimed is:

1. A Ge channel device comprising:
a Ge channel layer;
a Si-containing interface layer formed on said Ge channel layer;
a La₂O₃ layer formed on said interface layer; and
an electrically conductive layer formed on said La₂O₃ layer.

2. A Ge channel device as claimed in claim 1, wherein said Si-containing interface layer has a layer thickness of 0.5 to 2 nm.

3. A Ge channel device as claimed in claim 1, wherein said Si-containing interface layer contains either Si or silicate or La-silicate.

4. A Ge channel device as claimed in claim 2, wherein said Si-containing interface layer contains either Si or silicate or La-silicate.

5. A Ge channel device as claimed in claim 1, wherein in order to operate said device as a MOS capacitor, a second electrically conductive layer is formed on a surface of said Ge channel layer opposite to the surface thereof on which said interface layer is formed.

6. A Ge channel device as claimed in claim 2, wherein in order to operate said device as a MOS capacitor, a second electrically conductive layer is formed on a surface of said Ge channel layer opposite to the surface thereof on which said interface layer is formed.

7. A Ge channel device as claimed in claim 3, wherein in order to operate said device as a MOS capacitor, a second electrically conductive layer is formed on a surface of said Ge channel layer opposite to the surface thereof on which said interface layer is formed.

8. A Ge channel device as claimed in claim 4, wherein in order to operate said device as a MOS capacitor, a second electrically conductive layer is formed on a surface of said Ge channel layer opposite to the surface thereof on which said interface layer is formed.

9. A Ge channel device as claimed in claim 1, wherein said Ge channel layer contains source and drain regions.

10. A Ge channel device as claimed in claim 2, wherein said Ge channel layer contains source and drain regions.

11. A Ge channel device as claimed in claim 3, wherein said Ge channel layer contains source and drain regions.

12. A Ge channel device as claimed in claim 4, wherein said Ge channel layer contains source and drain regions.

13. A method for fabricating a Ge channel device, comprising the steps of:
forming a Si-containing interface layer on a channel layer of Ge;
forming a gate insulating film of La₂O₃ on said interface layer; and
forming an electrically conductive material layer on said gate insulating film.

14. A method for fabricating a Ge channel device as claimed in claim 13, wherein said interface layer has a layer thickness of 0.5 to 2 nm.

15. A method for fabricating a Ge channel device as claimed in claim 13, further comprising, following the step of forming said electrically conductive material layer, heat-treating said channel layer on which said interface layer and said gate insulating film have been formed.

16. A method for fabricating a Ge channel device as claimed in claim 14, further comprising, following the step of forming said electrically conductive material layer, heat-treating said channel layer on which said interface layer and said gate insulating film have been formed.

17. A method for fabricating a Ge channel device as claimed in claim 13, wherein the step of forming said Si-containing interface layer on said channel layer of Ge is carried out after removing a Ge oxide film grown on a surface of said channel layer on which said interface layer is to be formed.

18. A method for fabricating a Ge channel device as claimed in claim 14, wherein the step of forming said Si-containing interface layer on said channel layer of Ge is carried out after removing a Ge oxide film grown on a surface of said channel layer on which said interface layer is to be formed.

19. A method for fabricating a Ge channel device as claimed in claim 15, wherein the step of forming said Si-containing interface layer on said channel layer of Ge is carried out after removing a Ge oxide film grown on a surface of said channel layer on which said interface layer is to be formed.

20. A method for fabricating a Ge channel device as claimed in claim 16, wherein the step of forming said Si-containing interface layer on said channel layer of Ge is carried out after removing a Ge oxide film grown on a surface of said channel layer on which said interface layer is to be formed.
